(19) United States
(12) Patent Application Publication
(10) Pub. No.: US 2014/0252341 A1
(43) Pub. Date: Sep. 11, 2014

(54) PYRROLO PYRROLEDIONE-THENEQUINONE COMPOUND, AND PREPARATION PROCESS AND USE THEREOF

(71) Applicant: INSTITUTE OF CHEMISTRY, CHINESE ACADEMY OF SCIENCES, Haidian District Beijing (CN)

(72) Inventors: Yali Qiao, Haidian District Beijing (CN); Jing Zhang, Haidian District Beijing (CN); Wei Xu, Haidian District Beijing (CN); Daoben Zhu, Haidian District Beijing (CN)

(73) Assignee: INSTITUTE OF CHEMISTRY, CHINESE ACADEMY OF SCIENCES, Haidian District Beijing (CN)

(21) Appl. No.: 14/350,610

(22) PCT Filed: Oct. 10, 2012
(86) PCT No.: PCT/CN2012/001366

§ 371 Date: Apr. 9, 2014

(30) Foreign Application Priority Data
Oct. 11, 2011 (CN) 201110306463.7

(51) Int. Cl. H01L 51/00; H01L 51/05

(52) U.S. Cl. CPC H01L 51/0071; H01L 51/0512
USPC 257/40; 548/453

(57) ABSTRACT

Disclosed are a pyrrolo-pyrroledione-thiophenequinone compound as shown by formula I, a preparation process thereof and the use thereof as an organic semiconductor material. The preparation process for the compound of formula I comprises reacting NaH, an α-bromine substituted pyrrolo-pyrroledione-thiophene oligomer as shown by formula II and malononitrile sodium salt, in the presence of catalytic Pd(PPh₃)₄, and then adding to the reaction system saturated bromine water to carry out an oxidation reaction, so as to obtain the compound of formula I. The compound of formula I has a good field effect performance, an electron mobility of above 0.1 cm²V⁻¹s⁻¹, an on/off current ratio up to 10⁵, and is stable in air.

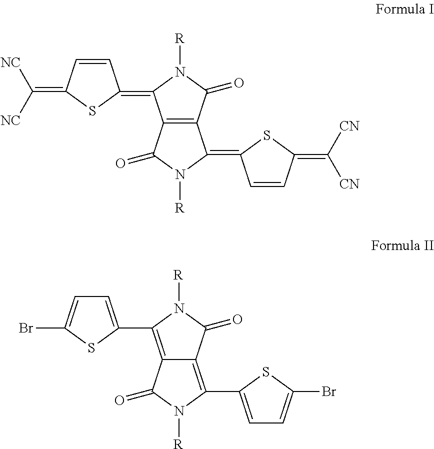

### TECHNICAL FIELD

The present invention relates to organic semiconductor materials for field effect transistors, particularly to pyrrolo-pyrroledione-thiophenequinone compounds, process and use thereof.

### TECHNICAL BACKGROUNDS

Organic Field Effect Transistor (OFET) has caused wide concern after it first appeared in 1986 (Tsumura, A.; Koezuka, H.; Ando, T. Appl. Phys. Lett. 1986, 49, 1210) because of its potential application values in large area sensor, RFID tag, electronic paper and large screen display. Compared with inorganic transistor, OFET has the advantages of low-cost, light-weight and good flexibility. In recent years, OFET has developed quickly and became one of the most important organic electronic devices (Zaumseil, J., Sirringhaus, H., Chem. Rev. 2007, 107, 1296-1323; Murphy, A. R., Frechet, J. M. J., Chem. Rev. 2007, 107, 1066-1096; Sun Y., Liu Y. Q., Zhu D. B., J. Mater. Chem., 2005, 15, 53-65.).

Currently, p-type organic semiconductor has not only been comparable with the traditional inorganic si-based material in the aspect of field effect mobility (Klauk, H., Halik, M., Zschieschang, U., Schmid, G., Radlik, W., Weber, W., J. Appl. Phys. 2002, 92, 5259-5263; Katz, H. E., Chem. Mater. 2004, 16, 4748-4756.), but also achieved a good stability in air. However, the n-type organic semiconductor usually has a relatively low field effect mobility and a bad air stability. Thus its development is behind p-type semiconductor. Recently, since n-type semiconductor plays an important role in constructing bipolar transistor and logic complementary circuit, high-performance n-type semiconductor material stable in air arouses more and more interests of the researchers (Usta, H., Risko, C., Wang, Z. M., Huang, H., Deliomeroglu, M. K., Zhukhovitskiy, A., Facchetti, A., Marks, T. J., J. Am. Chem. Soc. 2009, 131, 5586-5608; Ling, M. M., Erk, P., Gomez, M., Koenemann, M., Locklin, J., Bao, Z. N., Adv. Mater. 2007, 19, 1123-1127; Gsanger, M., Oh, J. H.; Konemann, M., Hoffken, H. W., Krause, A. M., Bao, Z. N., Wurthner, F., Angew. Chem. Int. Edit. 2010, 49, 740-743.). The number of reports about solution processible n-type semiconductor materials with high performance and air stability increases rapidly (Gao, X. K., Di, C. A., Hu, Y. B., Yang, X. D., Fan, H. Y., Zhang, F., Liu, Y. Q., Li, H. X., Zhu, D. B., J. Am. Chem. Soc. 2010, 132, 3697-3699; Hu, Y. B., Gao, X. K., Di, C. A., Yang, X. D., Zhang, F., Liu, Y. Q., Li, H. X., Zhu, D. B., Chem. Mater. 2011, 23, 1204-1215.), and the design and synthesis of n-type organic semiconductor have became hot research areas.

TCNQ-type compounds which are based on quinone-type structure of thiophene oligomer and which are used as novel n-type semiconductor materials have excellent overall performances: high performance, stable in air, and some of them are solution processible. Therefore, such TCNQ-type compounds show good application prospects in OFET (Handa, S., Miyazaki, E., Takimiya, K., Kunugi, Y., J. Am. Chem. Soc. 2007, 129, 11684-11685; Suzuki, Y., Miyazaki, E., Takimiya, K., J. Am. Chem. Soc. 2010, 132, 10453-10466; Suzuki, Y., Shimawaki, M., Miyazaki, E., Osaka, I., Takimiya, K., Chem. Mater. 2011, 23, 795-804.). Nowadays, the design of this kind of materials mainly includes: modifying the mother nucleus of oligomeric thiophene with a soluble group or adjusting the types of substituents on the ends to improve the solubility of the materials and the orderliness of the accumulation of molecules in thin film so as to achieve the finial purpose of increasing the overall performances of the materials. However, there are no reports on optimizing molecule performances through changing the structure of the mother nucleus of oligomeric thiophene.

### Contents of Invention

An object of present invention is to provide pyrrolo-pyrroledione-thiophenequinone compounds, the preparation process and the use thereof.

The general formula of pyrrolo-pyrroledione-thiophenequinone compounds provided in the present application is shown by Formula I:

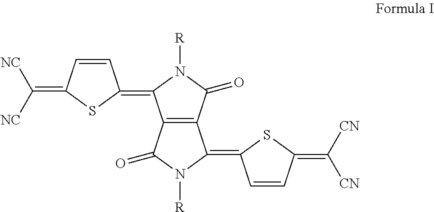

In Formula I, R is hydrogen, alkyl with a total number of 8 to 20 carbon atoms or alkoxy with a total number of 8 to 20 carbon atoms, preferably branched alkyl with a total number of 8 carbon atoms or branched alkyl with a total number of 16 carbon atoms.

The process of preparing the compounds represented by Formula I provided in the present invention comprises the following steps: under the catalytic action of Palladium(0) tetrakis(triphenylphosphine) (Pd(PPh₃)₄), mix sodium hydride, α-bromine substituted pyrrolo-pyrroledione-thiophene oligomer represented by Formula II and malononitrile sodium salt uniformly to carry out nucleophilic substitution reaction to form divalent anionic intermediate, and then add saturated bromine water into the reaction system to carry out oxidation reaction. The compound represented by Formula I is obtained after the reactions.

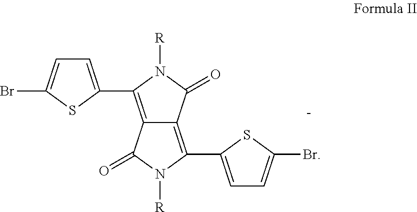

In Formula II, R is hydrogen, alkyl with a total number of 8 to 20 carbon atoms or alkoxy with a total number of 8 to 20 carbon atoms, preferably R is branched alkyl with a total number of 8 carbon atoms or branched alkyl with a total number of 16 carbon atoms.

The reaction scheme of this process is shown in FIG. 1.

In the process, the ratio of sodium hydride, α-bromine substituted pyrrolo-pyrroledione-thiophene oligomer represented by Formula II, malononitrile sodium salt and saturated bromine water is 4.63-5.56 mmol: 0.58-0.61 mmol: 1.39-1.45 mmol: 25-30 mL, preferably 4.63 mmol: 0.58 mmol: 1.39 mmol: 25 mL.

In the step of nucleophilic substitution reaction (namely, Takahashi coupling reaction), the temperature is 90-110° C., preferably 100° C. The time is 4-6 hours, preferably 4.5 hours. This nucleophilic substitution reaction step achieves the substitution for α-position of thiophene in precursory compound α-bromine substituted pyrrolo-pyrroledione-thiophene oligomer by malononitrile group.

In the step of oxidation reaction, the temperature is 0-25° C., preferably 25° C. The time is 2-3 hours, preferably 2.5 hours.

Both the nucleophilic substitution reaction and the oxidation reaction are carried out in a solvent and under an inert atmosphere. Said solvent is selected from at least one of ethylene glycol dimethyl ether, tetrahydrofuran and N,N-dimethylformamide dried by sodium, preferably ethylene glycol dimethyl ether. Said inert atmosphere is nitrogen atmosphere or argon atmosphere.

The reactant malononitrile sodium salt used in this process is formed in situ from sodium hydride and malononitrile through a conventional method. The separation of a dark purple precipitate from the reaction system indicates the formation of the divalent anionic intermediate.

The process of preparing the compounds represented by Formula I provided above can further comprise the following steps: when the oxidation reaction is finished, add dichloromethane into the reaction system for extraction; combine organic phases after extraction; wash the organic phase with saturated sodium chloride aqueous solution, dry the organic phase and carry out column chromatography. The eluent used is the mixed solution of petroleum ether and dichloromethane with the volume ratio of 1:2. Recrystallization with dichloromethane after the column chromatography can be conducted to obtain the purified compounds represented by Formula I.

The semiconductor layer formed from the compound represented by Formula I provided in the present invention of an organic field effect transistor is also within the scope of the present invention.

The present invention also provides a n-type organic field effect transistor which is composed of, from bottom to up, substrate, insulator layer, semiconductor layer, and source electrode layer and drain electrode layer located in the same layer; said source electrode layer and drain electrode layer do not contact with each other; wherein the material forming said semiconductor layer is a compound of Formula I provided in the present invention.

The material forming the substrate of the organic field effect transistor is selected from at least one of glass, ceramic and silicon wafer, preferably silicon wafer.

The material forming said insulator layer is selected from at least one of silica, n-octadecyltrichlorosilane modified silica, aluminium oxide, polyvinylpyrrolidone and polymethylmethacrylate, preferably silica. The thickness of said insulator layer is 300-500 nm, preferably 500 nm. As for n-octadecyl trichlorosilane (OTS) modified silica, the modification method of OTS is a conventional method and is OTS monomolecular layer modification.

The material forming said source electrode layer and drain electrode layer is selected from at least one of gold, silver and aluminum, preferably gold. The thickness of source electrode layer or drain electrode layer is 20-30 nm, preferably 30 nm.

The thickness of said semiconductor layer is 50-80 nm, preferably 50 nm.

The aforesaid n-type organic field effect transistor can be produced by a conventional preparation method. For example, the method can include the following steps: preparing on the substrate the following layers from bottom to up: the insulator layer, the semiconductor layer, and the source electrode layer and drain electrode layer so as to provide said n-type organic field effect transistor.

In the method, in the step of preparing said insulator layer, the preparation includes in situ thermal growth or plasma enhanced chemical vapor deposition. In the step of preparing said semiconductor layer, the preparation includes spin coating, drop-casting or vacuum evaporation. In the step of preparing said source electrode layer and drain electrode layer, the preparation includes vacuum evaporation, plasma enhanced chemical vapor deposition or printing.

The present invention provides quinone-type compounds with pyrrolo-pyrroledione-thiophene oligomer as mother nucleus and terminated by dicyanomethylene. The present invention also provides a process to synthesize successfully pyrrolo-pyrroledione-thiophenequinones through zero-valent Pd catalyzed Takahashi coupling reaction and oxidizing condition of saturated bromine water. This process has a short procedure and a low cost. This kind of compounds has the following unique advantages because of the introduction of pyrrolo-pyrroledione group: first, various substituents (for example, various type of alkyl chains: linear chains or branch chains, etc) can be introduced on the two nitrogen atoms of pyrrolo-pyrroledione unit so as to regulate the solubility of the compounds and improve the accumulation orderliness of molecules in thin film; second, the synthesis process is quite simple; and third, the quinone structure terminated by dicyanomethylene is maintained so that the compounds have lower LUMO energy level in order to meet the requirements on air-stable n-type semiconductor. Hence, this kind of compounds is excellent semiconductor material for n-type organic field effect transistor and has excellent field effect performances. The electronic mobility of said compounds is more than 0.1 cm²V⁻¹s⁻¹ (the electronic mobility of filed effect device of semiconductor layer prepared through vacuum evaporation is up to 0.3 cm²V⁻¹s⁻¹; and the electronic mobility of filed effect device of semiconductor layer prepared through spin coating is up to 0.35 cm²V⁻¹ s⁻¹). The on/off current ratio of the compounds reaches up to 10⁵, and this kind of compounds has stable performances in air. Thus these compounds have important application values.

### BRIEF DESCRIPTION OF THE DRAWINGS

FIG. 1 is a synthetic scheme of pyrrolo-pyrroledione-thiophenequinone molecule.

FIG. 2 is a schematic diagram for field effect transistor with pyrrolo-pyrroledione-thiophenequinone molecule as semiconductor active layer.

FIG. 3 is the output characteristic curve of field effect transistor having the material of Example 1.

FIG. 4 is the transfer characteristic curve of field effect transistor with the material of Example 1 under the source and drain voltage of 100 V.

FIG. 5 is the output characteristic curve of field effect transistor having material of Example 2.

FIG. 6 is the transfer characteristic curve of field effect transistor with the material of Example 2 under the source and drain voltage of 100 V.

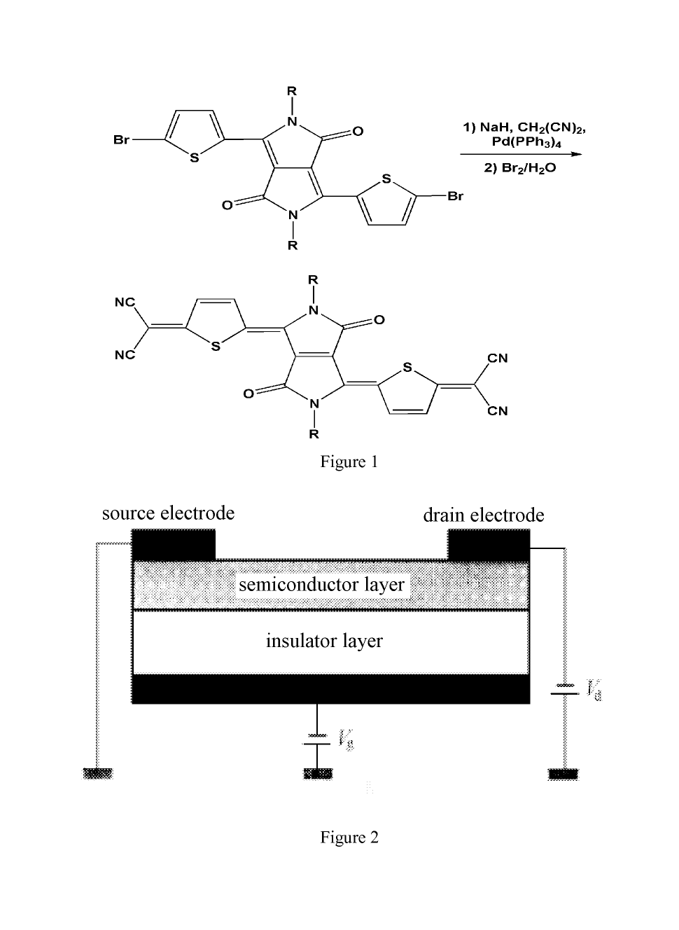

### EMBODIMENTS OF THE INVENTION

The present invention will be further explained in combination with working Examples, but the present invention is not limited to these Examples. The methods mentioned all are conventional methods except stated otherwise. The materials mentioned all are commercial available except stated otherwise. The output characteristic curve and transfer characteristic curve under the source and drain voltages of 100 V of n-type organic field effect transistor prepared in the following Examples are tested by Keithley 4200 type semiconductor tester and 6150 type probe station under air.

### EXAMPLE 1

### Synthesis of Compound (a) and Preparation of n-type Organic Field Effect Transistor

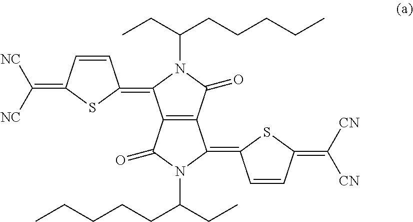 [SMILES: CCCCCC(CC)N1C(=O)C2=C(C(=O)N(C(CC)CCCCC)/C2=c2\ccc(=C(C#N)C#N)s2)/C1=c1/ccc(=C(C#N)C#N)s1] [0034] 1) Synthesizing Compound (a):

Under the protection of nitrogen, sodium hydride (0.111 g, 4.63 mmol) was suspended in ethylene glycol dimethyl ether (10 mL), and the temperature was decreased to 0° C. malononitrile (0.092 g, 1.39 mmol) was added slowly into the system and then stirred for 10 minutes at this temperature. The ice-bath was removed and the system was warmed to room temperature and stirred for 30 minutes. α-bromine substituted pyrrolo-pyrroledione-thiophene oligomer precursor wherein R is 2-ethyl-n-hexyl alkyl chain (0.393 g, 0.58 mmol) and palladium(0) tetrakis(triphenylphosphine) (0.067 g, 0.058 mmol) were added into the system sequentially, and the system was heated to reflux(the temperature was 100° C.). With the passing of time, a dark purple precipitate separated out from the system one hour later, indicating that divalent anionic intermediate was formed. The system was cooled to room temperature 4.5 hours later, and then cooled to 0° C. by ice bath. Saturated bromine water (25 mL) was added to the system dropwise, and then the system was stirred for 30 minutes at this temperature. The system was warmed to room temperature (25° C.) and stirred for 2.5 hours. Dichloromethane (50 mL×3) was added to the system for extraction, and the organic phases were combined. The combined organic phase was washed with saturated sodium chloride aqueous solution, and dried with anhydrous magnesium sulfate. The organic phase was filtered under vacuum, rotary evaporated to dry and the resulting residue was purified through column chromatography (petroleum ether:dichloromethane=1:2). After recrystallization with dichloromethane, 0.230 g olive green powered product was obtained, yield 61%, which is Compound (a) covered by general formula I provided in the present invention.

### Melting Point: 329 ° C.

The structural data of Compound (a) is shown as follows:

¹H NMR (400 MHz, CDCl₃) δ9.42 (d, J=5.8Hz, 2H), 7.38 (d, J=5.8 Hz, 2H), 3.99 (m, 4H), 1.90 (m, 2H), 1.42-1.27 (m, 16H), 0.97-0.88 (m, 12H); high resolution mass analysis (m/e): calculated value 650.2498, measured value 650.2504.

It can be seen that the compound is structurally correct and is the target compound.
2) Preparing n-type Organic Field Effect Transistor:

This product was evaporated onto a Si wafer substrate with a silica layer (thickness 500 nm) modified by n-octadecyltrichlorosilane (OTS) under the condition of vacuum degree of 4×10⁻⁴ Pa at the speed of 0.1-0.5 A/s. The semiconductor layer was composed of Compound (a) covered by Formula I prepared in Example 1, with the thickness of 50 nm. Then gold electrodes as source electrode and drain electrode were deposited under vacuum, with thickness of 30 nm, to provide the n-type organic field effect transistor of the present invention.

This n-type organic field effect transistor, as shown in FIG. 2, was composed of, from bottom to up: substrate, insulator layer, semiconductor layer, and source electrode layer and drain electrode layer located in the same layer; said source electrode layer and drain electrode layer do not contact with each other; wherein the material forming said semiconductor layer was Compound (a) covered by Formula I as prepared in Example 1.

The material forming the substrate was silicon wafer; the material forming said insulator layer was silica; the thickness of said insulator layer was 500 nm; the material forming said source electrode layer and drain electrode layer was gold; the thicknesses of both source electrode layer and drain electrode layer were 30 nm; and the thickness of said semiconductor layer was 50 nm.

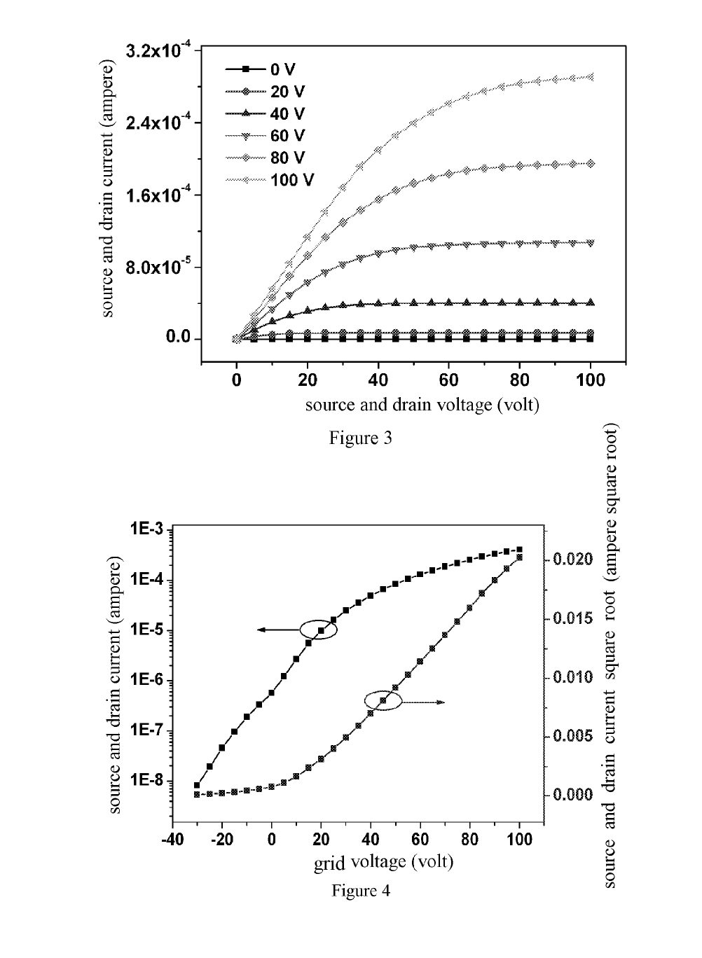

The organic field effect transistor prepared in this Example was tested by Keithley 4200 type semiconductor tester and 6150 type probe station under air. FIGS. 3 and 4 show the output characteristic curve and transfer characteristic curve under the source and drain voltage of 100 V of the field effect transistor prepared in said Example. It can be seen from the Figures that the filed effect electronic mobility on the basis of this product is up to 0.3 cm²V⁻¹s⁻¹, and the on/off current ratio is up to 10⁵.

### EXAMPLE 2

### Synthesis of Compound (b) and Preparation of n-type Organic Field Effect Transistor

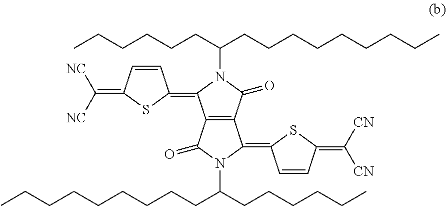 [SMILES: CCCCCCCCCC(CCCCCC)N1C(=O)C2=C(C(=O)N(C(CCCCCC)CCCCCCCCC)/C2=c2\ccc(=C(C#N)C#N)s2)/C1=c1/ccc(=C(C#N)C#N)s1] [0044] 1) Synthesizing Compound (b):

Under the protection of nitrogen, sodium hydride (0.111 g, 4.63 mmol) was suspended in ethylene glycol dimethyl ether (10 mL), and the temperature was decreased to 0° C. malononitrile (0.092 g, 1.39 mmol) was added slowly into the system and then stirred for 10 minutes at this temperature. The ice-bath was removed and the system was warmed to room temperature and stirred for 30 minutes. α-bromine substituted pyrrolo-pyrroledione-thiophene oligomer precursor wherein R is 2-hexyl-n-decyl alkyl chain (0.522 g, 0.58 mmol) and palladium(0) tetrakis(triphenylphosphine) (0.067 g, 0.058 mmol) were added into the system sequentially, and the system was heated to reflux(the temperature was 100° C.). With the passing of time, a dark purple precipitate separated out from the system one hour later, indicating that divalent anionic intermediate was formed. The system was cooled to room temperature 4.5 hours later, and then cooled to 0° C. by ice bath. Saturated bromine water (25 mL) was added to the system dropwise, and then the system was stirred for 30 minutes at this temperature. The system was warmed to room temperature (25° C.) and stirred for 2.5 hours. Dichloromethane (50 mL×3) was added to the system for extraction, and the organic phases were combined. The combined organic phase was washed with saturated sodium chloride aqueous solution, and dried with anhydrous magnesium sulfate. The organic phase was filtered under vacuum, rotary evaporated to dry and the resulting residue was purified through column chromatography (petroleum ethendichloromethane=1:1). After recrystallization with mixture of dichloromethane and petroleum ether, 0.170 g olive green powered product was obtained, yield 34%, which is Compound (b) covered by general formula I provided in the present invention.

### Melting Point: 207 ° C.

The structural data of Compound (b) is shown as follows:

¹H NMR (400 MHz, CDCl₃) δ9.42 (d, J=5.6 Hz, 2H), 7.38 (d, J=5.7Hz, 2H), 3.99 (m, 4H), 1.92 (m, 2H), 1.37-1.25 (m, 48H), 0.97-0.88 (m, 12H); high resolution mass analysis (m/e): calculated value 874.5002, measured value 874.5012.

It can be seen that the compound is structurally correct and is the target compound.
2) Preparing n-type Organic Field Effect Transistor:

The product was formulated into a trichloromethane solution and was spin-coated uniformly onto a Si wafer substrate with a silica layer (thickness 500 nm) modified by n-octadecyltrichlorosilane (OTS) at the rate of 2000 rpm. The semiconductor layer was composed of Compound (b) covered by Formula I prepared in this Example, with the thickness of 50 nm. Then gold electrodes as source electrode and drain electrode were deposited under vacuum, with thickness of 30 nm, to provide the n-type organic field effect transistor of the present invention.

This n-type organic field effect transistor, as shown in FIG. 2, was composed of, from bottom to up: substrate, insulator layer, semiconductor layer, and source electrode layer and drain electrode layer located in the same layer; said source electrode layer and drain electrode layer do not contact with each other; wherein the material forming said semiconductor layer was Compound (b) covered by Formula I as prepared in Example 2.

The material forming the substrate was silicon wafer; the material forming said insulator layer was silica; the thickness of said insulator layer was 500 nm; the material forming said source electrode layer and drain electrode layer was gold; the thicknesses of both source electrode layer and drain electrode layer are 30 nm; and the thickness of said semiconductor layer was 50 nm.

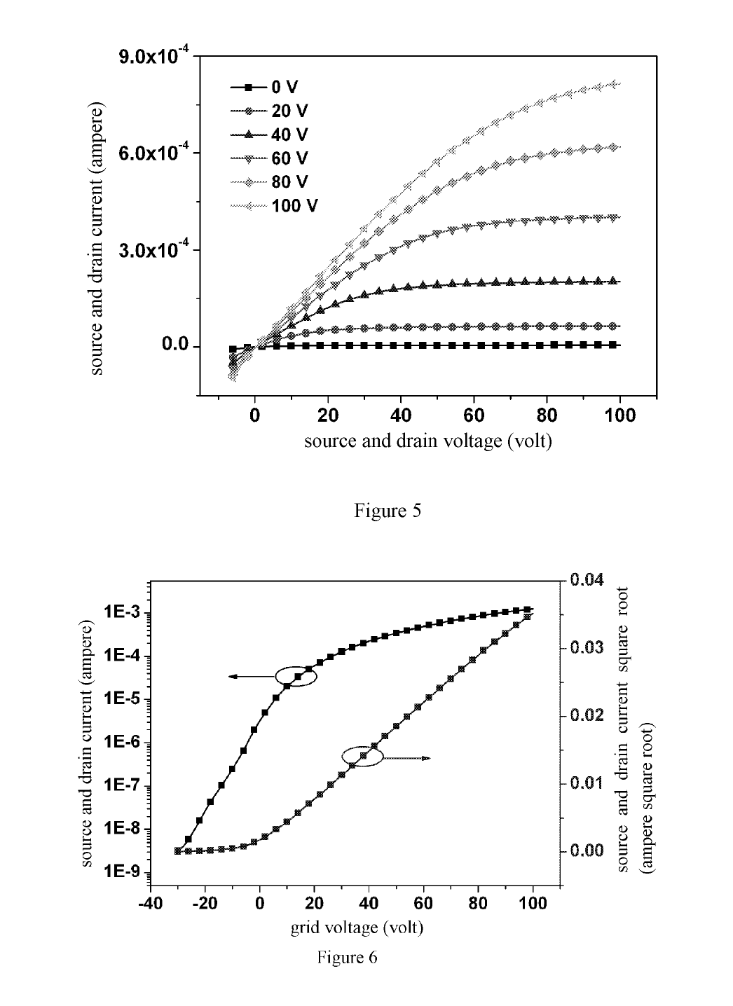

The organic field effect transistor prepared in this Example was tested by Keithley 4200 type semiconductor tester and 6150 type probe station under air. FIGS. 5 and 6 show the output characteristic curve and transfer characteristic curve under the source and drain voltages of 100 V of the field effect transistor prepared in said Example. It can be seen from the Figures that the filed effect electronic mobility on the basis of this product is up to 0.35 cm²V⁻¹s⁻¹, and the on/off current ratio is up to 10⁵.

1. A pyrrolo-pyrroledione-thiophenequinone compound represented by Formula I, 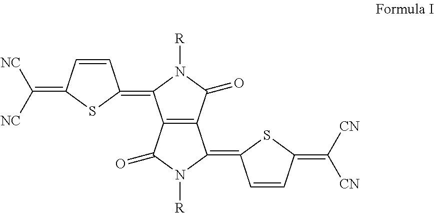
wherein, in Formula I, R is hydrogen, alkyl with a total number of 8 to 20 carbon atoms or alkoxy with a total number of 8 to 20 carbon atoms.

2. The compound according to claim 1, wherein in Formula I, R is branched alkyl with a total number of 8 carbon atoms or branched alkyl with a total number of 16 carbon atoms.

3. A process for preparing the compound of claim 1, comprising the steps of:
under the catalysis of palladium(0) tetrakis(triphenylphosphine), mixing sodium hydride, α-bromine substituted pyrrolo-pyrroledione-thiophene oligomer represented by Formula II and malononitrile sodium salt uniformly to carry out a nucleophilic substitution reaction to form a divalent anionic intermediate, and then adding saturated bromine water to the reaction system to carry out an oxidation reaction; wherein, in Formula II, 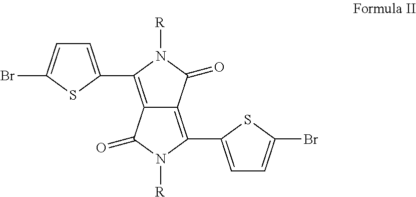
R is hydrogen, alkyl with a total number of 8 to 20 carbon atoms or alkoxy with a total number of 8 to 20 carbon atoms,
so as to provide the compound represented by Formula I.

4. The process according to claim 3, wherein in Formula II, R is branched alkyl with a total number of 8 carbon atoms or branched alkyl with a total number of 16 carbon atoms.

5. The process according to claim 3, wherein the ratio of said sodium hydride, α-bromine substituted pyrrolo-pyrroledione-thiophene oligomer represented by Formula II, malononitrile sodium salt and saturated bromine water is 4.63-5.56 mmol: 0.58-0.61 mmol: 1.39-1.45 mmol: 25-30 mL.

6. The process according to claim 3, wherein in the nucleophilic substitution reaction step, the temperature is 90-110° C. and the period is 4-6 hours, and in the oxidation reaction step, the temperature is 0-25° C. and the period is 2-3 hours.

7. The process according to claim 3, wherein both the nucleophilic substitution reaction and the oxidation reaction are carried out in a solvent and under an inert atmosphere; wherein said solvent is selected from the group consisting of ethylene glycol dimethyl ether, tetrahydrofuran, N,N-dimethylformamide or a combination thereof dried by sodium; and said inert atmosphere is nitrogen atmosphere or argon atmosphere.

8. A semiconductor layer of an organic field effect transistor, wherein the semiconductor layer is formed from one or more compounds according to claim 1.

9. A n-type organic field effect transistor which is composed of, from bottom to top: a substrate, an insulator layer, a semiconductor layer, and a source electrode layer and a drain electrode layer located in the same layer; said source electrode layer and drain electrode layer do not contact each other; and wherein the material forming said semiconductor layer is one or more compounds according to claim 1.

10. The transistor according to claim 9, wherein the material forming the substrate is selected from the group consisting of glass, ceramic, silicon wafer, and a combination thereof;
the material forming said insulator layer is selected from the group consisting of silica, n-octadecyltrichlorosilane modified silica, aluminium oxide, polyvinylpyrrolidone, polymethylmethacrylate, and a combination thereof; wherein the thickness of said insulator layer is 300-500 nm;
the material forming said source electrode layer and drain electrode layer is selected from the group consisting of gold, silver, aluminum, and a combination thereof; and wherein the thickness of the source electrode layer or drain electrode layer is 20-30 nm;
the thickness of said semiconductor layer is 50-80 nm, preferably 50 nm.

11. The process according to claim 5, wherein the ratio of said sodium hydride, α-bromine substituted pyrrolo-pyrroledione-thiophene oligomer represented by Formula II, malononitrile sodium salt and saturated bromine water is 4.63 mmol: 0.58 mmol: 1.39 mmol: 25 mL.

12. The process according to claim 6, wherein in the nucleophilic substitution reaction step, the temperature is 100° C., and/or the period is 4.5 hours.

13. The process according to claim 6, wherein in the oxidation reaction step, the temperature is 25° C., and/or the period is 2.5 hours.

14. The process according to claim 7 wherein the solvent is ethylene glycol dimethyl ether.

15. The transistor according to claim 10, wherein the material forming the substrate is silicon wafer.

16. The transistor according to claim 10, wherein the material forming the insulator layer is silica.

17. The transistor according to claim 10, wherein the thickness of the insulator layer is 500 nm.

18. The transistor according to claim 10, wherein the material forming the source electrode layer and drain electrode layer is gold.

19. The transistor according to claim 10, wherein the thickness of the source electrode layer or drain electrode layer is 30 nm.

20. The transistor according to claim 10, wherein the thickness of the semiconductor layer is 50 nm.
